(19) United States
(12) Patent Application Publication
(10) Pub. No.: US 2024/0018699 A1
(43) Pub. Date: Jan. 18, 2024

(54) FABRIC STRUCTURE COMPRISING FLEXIBLE SOLAR CELLS

(71) Applicant: AUDI AG, Ingolstadt (DE)

(72) Inventors: Wojciech BRYMERSKI, Kornwestheim (DE); Julia FORSTER, Stockach (DE)

(73) Assignee: AUDI AG, Ingolstadt (DE)

(21) Appl. No.: 18/256,513

(22) PCT Filed: Oct. 13, 2021
(86) PCT No.: PCT/EP2021/078336

§ 371 Date: Jun. 8, 2023

(30) Foreign Application Priority Data
Dec. 11, 2020 (DE) 10 2020 133 068.5

(51) Int. Cl. D03D 1/00; H01L 31/0445; H01L 31/049; H01L 31/02; D03D 15/283

(52) U.S. Cl. CPC D03D 1/0088; H01L 31/0445; H01L 31/049; H01L 31/02013; D03D 15/283; D10B 2507/04; D10B 2505/12; D10B 2331/04

(57) ABSTRACT

A fabric structure includes a woven polyester fabric and a layer of butyl rubber disposed on the woven polyester fabric. The fabric structure includes a layer of polyacrylonitrile attached to the butyl rubber layer. The fabric structure includes at least one flexible thin-film solar cell element located on the polyacrylonitrile layer. The fabric structure includes a plurality of electrical connecting lines extending between the polyacrylonitrile layer and the butyl rubber layer and connected to the at least one solar cell element. The fabric structure forms part of a device, such as a convertible top, a carport covering, a sun shade, or a boat sail.

### TECHNICAL FIELD

The invention relates to a fabric structure comprising flexible solar cells, to a process for the production thereof, and to devices containing the fabric structure.

### BACKGROUND

It has already been proposed to combine solar cells with fabric materials.

DE 10 2010 026 221 A1 describes a known folding roof arrangement of a motor vehicle having a top which has several top segments which are foldable on one another in an open position of the top and flexibly designed, and into which top segments at least one, flexibly-designed solar module is integrated. The solar module is disposed between an outer UV-transparent layer (e.g., casting resin, PUR, EVA, PVB, . . . ) and an inner, flexibly-designed layer (film, knitted fabric, woven fabric, etc.).

EP 1 082 502 B1 discloses an awning with a frame and a movable awning covering which can be pulled out and removed. The awning covering has flexible solar modules on the upper side. The solar modules are applied as strips to the awning covering (fabric, etc.) and sealed via a coat of protective paint (coating). The frame contains a roller body onto which the awning covering can be rolled up. At least one storage cell is connected to the solar modules and mounted in the roller. It stores the electrical energy generated by the solar modules. The awning can be operated with the energy stored in the storage cell.

EP 3 097 591 A1 relates to a highly efficient, flexible photovoltaic sheet obtained by combining a very flexible, ultra-thin photovoltaic film with a very thin, prismatic, anti-reflection film that absorbs the energy of the solar radiation and corrects the angle of the solar rays.

### SUMMARY OF INVENTION

Against this background, the object of the invention according to the present disclosure is to provide a fabric structure, containing a solar cell, which combines high deformability and robustness against environmental influences with high energy efficiency, to a process for the production thereof, and to devices containing the fabric structure.

The object of the invention is achieved by a fabric structure having one or more of the features of the embodiments described herein, a process having one or more of the features of the embodiments described herein, and devices having one or more features of the embodiments described herein. Additional developments of the invention emerge from the description and the figure.

The subject matter according to one embodiment of the invention is a fabric structure having a woven polyester fabric on which a layer of butyl rubber is disposed. A layer of polyacrylonitrile is attached to the butyl rubber layer, and at least one, flexible, thin-film solar cell element is located on the polyacrylonitrile layer, the electrical connecting lines of the at least one solar cell element extending between the polyacrylonitrile layer and the butyl rubber layer. The combination of polyester fabric, butyl rubber, and polyacrylonitrile provides a dense composite. Thus, the solar cell is not susceptible to corrosion or short-circuiting. Butyl rubber and polyacrylonitrile yield a composite which is dense and in particular flexible.

In one embodiment, the layer thickness of the entire composite is from 1 mm to 5 mm. In one embodiment, the flexible, thin-film solar cell element has a layer thickness of 0.1 mm to 0.5 mm. In one embodiment, the thickness of the other layers is from 0.1 mm to 0.5 mm.

In one embodiment, the ends of the electrical connecting lines are coupled to an integrated connection plug. The plug can be integrated via the carrier layers (PAN, butyl rubber, and PES fabric) or via the entire composite, including solar cells.

In one embodiment, the at least one, flexible, thin-film solar cell element is attached to the layer of polyacrylonitrile by means of an adhesive layer or a printing paste.

In a further embodiment, a transparent protective layer is attached to the at least one, flexible, thin-film solar cell element. In one embodiment, the transparent protective layer comprises a transparent protective film. In one embodiment, the transparent protective film is a polyolefin film or a film of another transparent plastic material. In another embodiment, the transparent protective layer consists of a transparent and flexible casting resin.

In one embodiment, the at least one, flexible, thin-film solar cell element is a highly efficient, flexible photovoltaic film having at least one photovoltaic layer. In one embodiment, the photovoltaic layer consists of plate-form or layer photovoltaic cells. In one embodiment, the photovoltaic cells are thin-film cells made of amorphous silicon. In another embodiment, the photovoltaic cells are cells of the copper, indium, gallium, selenium mixture type (CIGS), the cadmium telluride type (CdTe), or the cadmium selenide type (CdS), the printable or non-printable organic type (OPV), or the “dye-sensitized solar cell” type (DSSC, DSC). In one embodiment, the photovoltaic layer is encapsulated between two, flexible polymer films. In one embodiment, the polymer films are copolymers of ethylene acrylic acid (EAA) or ethylene methyl acrylate (EMA).

The invention according to some embodiments also relates to a process for producing the fabric structure according to the invention. In the process, a layer of butyl rubber is first applied to a polyester fabric. Electrical connecting lines for connecting at least one, thin-film solar cell element are laid on the layer of butyl rubber. A layer of polyacrylonitrile is applied over the electrical connecting lines in such a way that the ends of the electrical connecting lines extend through the layer of polyacrylonitrile. At least one, thin-film solar cell element is then attached to the layer of polyacrylonitrile and connected to the electrical connecting lines. In another embodiment of the process, the other end of the electrical connecting lines is connected to a connection plug. In one embodiment of the process, the flexible, thin-film solar cell element is attached to the layer of polyacrylonitrile by means of an adhesive layer or a printing paste. In a further embodiment of the process, a transparent protective layer is attached to the flexible, thin-film solar cell element. In one embodiment, the transparent protective layer is a transparent protective film. In another embodiment, the transparent protective layer is produced by applying a transparent and flexible casting resin. Additionally or alternatively, the at least one, thin-film solar cell element can be sewn to the composite of polyacral nitrile, butyl rubber, and polyester fabric with threads made of polyester in the outer edge of the composite. As a result, the fabric structure is somewhat even more stable and even less prone to delamination.

The invention according to some embodiments also relates to devices which comprise or are manufactured from the fabric structure according to one or more embodiments of the invention. This includes a convertible top comprising the fabric structure according to the invention, a carport covering comprising the fabric structure according to the invention, a sun shade comprising the fabric structure according to the invention, or a boat sail comprising the fabric structure according to the invention.

The advantages of the solution according to embodiments of the invention include that the fabric structure can withstand very high degrees of deformation without direct damage, exhibits waterproofness or resistance to environmental influences, and has a high energy efficiency (currently, a power of about 120 W/m² is possible).

Further advantages and embodiments of the invention emerge from the description and the accompanying drawing.

It is understood that the aforementioned features and those still to be explained below can be used not only in the respectively specified combination, but also in other combinations or alone, without departing from the scope of the present invention.

### BRIEF DESCRIPTION OF THE FIGURE

The invention is schematically illustrated in the drawing on the basis of one embodiment and described further with reference to the drawing. In the figure:

FIG. 1 shows an embodiment of the fabric structure according to the invention.

### DETAILED DESCRIPTION

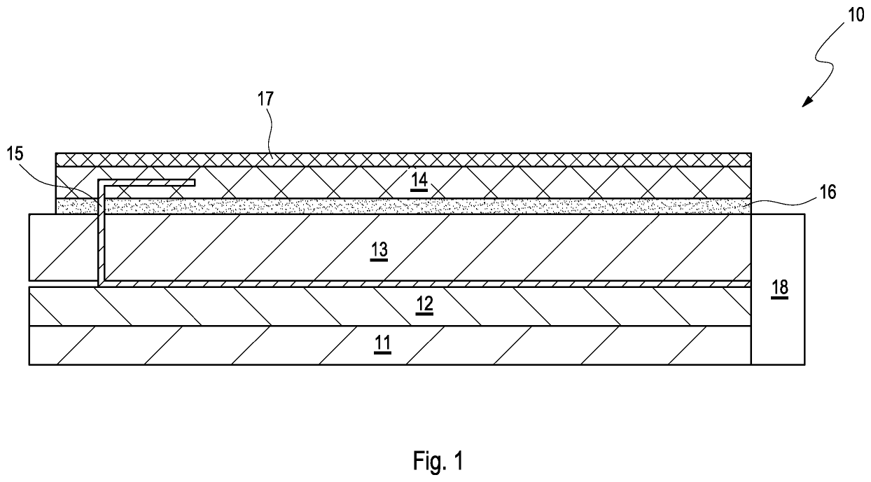

FIG. 1 shows an embodiment of the fabric structure 10 according to the invention. A layer 12 of butyl rubber is disposed on a polyester fabric 11, to which layer a layer 13 made of polyacrylonitrile is attached. At least one, flexible, thin-film solar cell element 14, the electrical connecting lines 15 of which extend between the polyacrylonitrile layer 13 and the butyl rubber layer 12, is located on the layer 13 of polyacrylonitrile. The electrical connecting lines 15 are connected at one end to the thin-film solar cell element 14, and at the other end to a connection plug 18. The flexible, thin-film solar cell element 14 is attached to the layer 13 of polyacrylonitrile by means of an adhesive layer 16 or a printing paste 16. In the embodiment shown, a transparent protective layer 17, e.g., a transparent protective film, is attached to the flexible, thin-film solar cell element 14. In another embodiment, the transparent protective layer 17 consists of a transparent and flexible casting resin.

### LIST OF REFERENCE NUMERALS

10 Fabric structure
11 Polyester fabric
12 Butyl rubber layer
13 Polyacrylonitrile layer
14 Thin-film solar cell element
15 Connecting lines
16 Adhesive layer/layer of printing paste
17 Transparent protective layer
18 Connection plug

1-10. (canceled)

11. A fabric structure comprising:
a polyester fabric;
a butyl rubber layer disposed on the polyester fabric;
a polyacrylonitrile layer attached to the butyl rubber layer; and
a flexible, thin-film solar cell element located on the polyacrylonitrile layer,
wherein the flexible, thin-film solar cell element is connected to a plurality of electrical connecting lines extending between the polyacrylonitrile layer and the butyl rubber layer.

12. A fabric structure according to claim 11, wherein the flexible, thin-film solar cell element is attached to the polyacrylonitrile layer by an adhesive layer or a printing paste.

13. A fabric structure according to claim 11, wherein a transparent protective layer is attached to the flexible, thin-film solar cell element.

14. A fabric structure according to claim 13, wherein the transparent protective layer comprises a transparent protective film.

15. A fabric structure according to claim 13, wherein the transparent protective layer consists of a transparent and flexible casting resin.

16. A fabric structure according to claim 11, wherein the fabric structure forms a part of a convertible top.

17. A fabric structure according to claim 11, wherein the fabric structure forms a part of a carport covering.

18. A fabric structure according to claim 11, wherein the fabric structure forms a part of a sun shade.

19. A fabric structure according to claim 11, wherein the fabric structure forms a part of a boat sail.

20. A process for producing a fabric structure, the process comprising:
applying a layer of butyl rubber to a polyester fabric;
disposing a plurality of electrical connecting lines on the butyl rubber layer;
applying a layer of polyacrylonitrile over the plurality of electrical connecting lines such that ends of the electrical connecting lines extend through the polyacrylonitrile layer;
attaching a flexible, thin-film solar cell element to the polyacrylonitrile layer; and
connecting the plurality of electrical connecting lines to the flexible, thin-film solar cell element.
